(19) United States
(12) Patent Application Publication
(10) Pub. No.: US 2018/0047898 A1
(43) Pub. Date: Feb. 15, 2018

(54) PROCESS FOR DEPOSITING POROUS ORGANOSILICATE GLASS FILMS FOR USE AS RESISTIVE RANDOM ACCESS MEMORY

(71) Applicant: VERSUM MATERIALS US, LLC, Tempe, AZ (US)

(72) Inventors: Robert Gordon RIDGEWAY, Quakertown, PA (US); Michael T. SAVO, Bethlehem, PA (US); Raymond Nicholas VRTIS, Orefield, PA (US); William Robert ENTLEY, Center Valley, PA (US); Xinjian LEI, Vista, CA (US); John Giles LANGAN, Carlsbad, CA (US)

(21) Appl. No.: 15/554,389

(22) PCT Filed: Mar. 8, 2016
(86) PCT No.: PCT/US2016/021377

§ 371 Date: Aug. 29, 2017

Related U.S. Application Data
(60) Provisional application No. 62/130,251, filed on Mar. 9, 2015.

(51) Int. Cl. H01L 45/00

(52) U.S. Cl. CPC H01L 45/1616; H01L 45/1641; H01L 45/145; H01L 45/08; H01L 45/1233

(57) ABSTRACT

A process for forming a resistive random-access memory device, the process comprising the steps of: depositing a first electrode on a substrate; forming a porous resistive memory material layer on the first electrode, wherein the porous resistive memory layer is formed by (i) depositing a gaseous composition comprising a silicon precursor and a porogen precursor and, once deposited, (ii) removing the porogen precursor by exposing the composition to UV radiation; and depositing a second electrode on top of the porous resistive memory material layer.

### BACKGROUND

The present development relates to a process for making a resistive random access memory (RRAM) device by employing chemical vapor deposition techniques. More specifically, the present development relates to making a resistive random access memory device by employing a plasma enhanced chemical vapor deposition (PECVD) process to deposit a gaseous mixture of a silicon-containing precursor and a porogen precursor followed by removal of the porogen by UV radiation.

Resistive random-access memory (RRAM) is a type of non-volatile random-access (RAM) computer memory that works by changing the resistance across a dielectric solid-state material often referred to as a memristor. RRAM involves generating defects in a thin oxide layer, known as oxygen vacancies (oxide bond locations where the oxygen has been removed), which can subsequently charge and drift under an electric field. The motion of oxygen ions and vacancies in the oxide would be analogous to the motion of electrons and holes in a semiconductor.

A range of materials and methods are employed in the prior art to make a RRAM device. For example, U.S. Publ. No. 2011/124174A provides a method of forming an electrode of a variable resistance memory device and a variable resistance semiconductor memory device which includes: forming a heat electrode; forming a variable resistance material layer on the heat electrode; and forming a top electrode on the variable resistance material layer wherein the heat electrode includes a nitride of a metal whose atomic radius is greater than that of titanium (Ti) and is formed through a thermal chemical vapor deposition (CVD) method without using plasma.

The reference entitled “Complementary and bipolar regimes of resistive switching in TiN/HfO₂/TiN stacks grown by atomic-layer deposition,” Egorov, K. V., et al., Phys. Status Solidi A, (2015) describes an atomic-layer deposition (ALD) technique in combination with in vacuo XPS analysis which is used to obtain fully ALD-grown planar TiN/HfO₂/TiN metal-insulator-metal structures for resistive random access memory memory elements.

The reference entitled “Resistive switching phenomena in TiOₓ nanoparticle layers for memory applications,” Goren, E., et al., Condens. Matter: 1-15 (2014) provides the electrical characteristics of a Co/TiOₓ/Co resistive memory device, fabricated by two different methods: ALD or sol gel.

The reference entitled “Self-Limited Switching in Ta₂O₅/TaOₓ Memristors Exhibiting Uniform Multilevel Changes in Resistance,” Kim, K. M., et al., (2015), Adv. Funct. Mater. 25: 1527-1534 describes a method of resolving the problem of non-uniformity in switching, caused by the random nature of the filamentary switching mechanism in many resistance switching memories based on transition metal oxide.

The reference entitled “Bipolar resistive switching and charge transport in silicon oxide memristor,” Mikhaylov, A. N., et al., (2015), Materials Science and Engineering: B 194: 48-54 describes reproducible bipolar resistive switching in SiOx-based thin-film memristor structures deposited by magnetron sputtering technique on the TiN/Ti metalized SiO₂/Si substrates.

US Publ. No. US 2013/264536A describes various embodiments of memresistor cells that comprise: (1) a substrate; (2) an electrical switch associated with the substrate; (3) an insulating layer; and (3) a resistive memory material. The resistive memory material is selected from the group consisting of SiOₓ, SiOₓH, SiOₓN_{y}, SiOₓN_{y}H, SiOₓC_{z}, SiOₓC_{z}H, and combinations thereof, wherein each of x, y and z are equal or greater than 1 or equal or less than 2. Additional embodiments of the present invention pertain to memresistor arrays that comprise: (1) a plurality of bit lines; (2) a plurality of word lines orthogonal to the bit lines; and (3) a plurality of said memresistor cells positioned between the word lines and the bit lines. Further embodiments of the present invention provide methods of making said memresistor cells and arrays.

The reference entitled “Nanoporous Silicon Oxide Memory,” Wang, G., et al. (2014) Nano Letters 14(8): 4694-4699 describes oxide-based two-terminal resistive random access memory to be considered for next-generation nonvolatile memory. The RRAM memory structure employs a nanoporous silicon oxide (SiOx) material which enables unipolar switching through its internal vertical nanogap.

The reference entitled “Resistive switches and memories from silicon oxide,” Yao, J., et al. (2010), Nano Lett. 10(10): 4105-4110 describes the use of Si oxide (SiOx) as a passive, insulating component in the construction of electronic devices.

The reference entitled “Silicon Oxide: A Non-innocent Surface for Molecular Electronics and Nanoelectronics Studies,” Yao, J., et al., (2010), Journal of the American Chemical Society 133(4): 941-948 describes the use of silicon oxide (SiOx) as a supportive and insulating medium.

The reference entitled “In situ imaging of the conducting filament in a silicon oxide resistive switch,” Yao, J., et al., (2012), Sci. Rep. 2 describes the growth and shrinkage of the silicon nanocrystals in response to different electrical stimuli show energetically viable transition processes in the silicon forms, offering evidence for the switching mechanism. The reference also provides insights into the electrical breakdown process in silicon oxide layers, which are ubiquitous in a host of electronic devices.

The reference entitled “Role of interfacial layer on complementary resistive switching in the TiN/HfOₓ/TiN resistive memory device,” Zhang, H. Z., et al. (2014), Appl. Phys. Lett describes the role of the bottom interfacial layer (IL) in enabling stable complementary resistive switching (CRS) in the TiN/HfOₓ/IL/TiN resistive memory device. Stable CRS is obtained for the TiN/HfOₓ/IL/TiN device, where a bottom IL comprising Hf and Ti sub-oxides resulted from the oxidation of TiN during the initial stages of atomic layer deposition of Hf Oₓ layer. In the TiN/HfOₓ/Pt device, where formation of the bottom IL is suppressed by the inert Pt metal, no CRS is observed. Oxygen-ion exchange between IL and the conductive path in Hf Oₓ layer is proposed to have caused the complementary bipolar switching behavior observed in the TiN/HfOₓ/IL/TiN device.

The reference entitled “Characterization of external resistance effect and performance optimization in unipolar-type SiOx-based resistive switching memory,” Zhou, F., et al., (2014), Applied Physics Letters 105(13) compares SiOx-based resistive random access memory devices with metal-insulator-metal structure to metal-insulator-semiconductor structures, and the effects of external resistance on device performance are characterized.

But in the above processes, depositing SiOx films and creating defects are taught as separate, independent steps, which is inefficient and economically disadvantageous as use of well known high volume manufacturing methods and certain tools are not readily available for such processes. A process is desired that condences deposition and defect creation in sequential steps within the same process platform. The present development provides such process.

### SUMMARY

In one aspect, the present development provides a process for forming a resistive random-access memory device, the process comprising the steps of: depositing a first electrode on a substrate; forming a porous resistive memory material layer on the first electrode, wherein the porous resistive memory layer is formed by (i) depositing a gaseous composition comprising a silicon precursor and a porogen precursor and, once deposited, (ii) removing the porogen precursor by exposing the composition to UV radiation; and depositing a second electrode on top of the porous resistive memory material layer.

### BRIEF DESCRIPTION OF THE DRAWINGS

FIG. 1 shows a schematic illustration of a vertically oriented electronic device made by the method of the present development;

FIG. 2 shows a schematic illustration of another vertically oriented electronic device made by the method of the present development;

FIG. 3A illustrates a current versus voltage plot of a forward voltage sweep that does not show increase in conductivity until high potentials are applied and a hard electrical breakdown or short circuit develops in the SiOx film, whereas the reverse sweep shows the impact of the short circuit as current density remains high during the sweep back to 0 Volts;

FIG. 3B illustrates a current versus voltage plot wherein the forward sweep in green shows a significant increase in conductivity at a very low applied voltage indicating that the SiOx film is too leaky or conductive resulting in a hard breakdown at a very low potential;

FIG. 3C illustrates a current versus voltage plot showing a hysteretic current, i.e., a voltage sweep showing activation at ca. 3.5 v and deactivation at ca. 10V;

FIG. 4A illustrates a current versus voltage plot of SiOx films deposited using varying porgen to structure former ratios showing a hard breakdown of the dielectric at 28 V of applied potential;

FIG. 4B illustrates a current versus voltage plot of SiOx films deposited using varying porgen to structure former ratios showing the hysteretic current-voltage profile of a resistive memory switching device;

FIG. 4C illustrates a current versus voltage plot of SiOx films deposited using varying porgen to structure former ratios showing a profile of a film that electrically breaks down at very low applied potentials and is not sufficiently insulating to serve as a memory switching device;

FIG. 5A illustrates a current versus voltage plot demonstrating hysteretic profiles for porous PECVD based SiOx films deposited using porogen to structure former ratios of 80:20;

FIG. 5B illustrates a current versus voltage plot demonstrating hysteretic profiles for porous PECVD based SiOx films deposited using porogen to structure former ratios of 85:15;

FIG. 6A illustrates a plot of signal retention of porous PECVD SiOx films based on reading ON and OFF states at 1V over an extended period; and

FIG. 6B illustrates a plot showing memory switching stability demonstrated for porous PECVD SiOx films for 1000 cycles.

### DETAILED DESCRIPTION

Embodiments of the present development are discussed in detail below. In describing embodiments, specific terminology is employed for the sake of clarity. However, the invention is not intended to be limited to the specific terminology so selected. While specific exemplary embodiments are discussed, it should be understood that this is done for illustration purposes only. A person skilled in the relevant art will recognize that other components and configurations can be used without parting from the spirit and scope of the development. All references cited herein are incorporated by reference as if each had been individually incorporated.

The present development provides a process for forming a resistive random-access memory device, the process comprising the steps of: depositing a first electrode on a substrate; forming a porous resistive memory material layer on the first electrode, wherein the porous resistive memory layer is formed by (i) depositing a gaseous composition comprising a silicon precursor and a porogen precursor and, once deposited, (ii) removing the porogen precursor by exposing the composition to UV radiation; and depositing a second electrode on top of the porous resistive memory material layer.

The device produced according to the present development is preferably a RRAM device wherein the apparatus comprises: a semi-conductor substrate; a plurality of electrodes comprising a conducting material; a resistive memory material comprising at least one porous silicon containing material; and at least one dielectric material comprised of an insulating material wherein at least a portion of the plurality of electrodes are proximal to the resistive memory material and wherein the apparatus is deposited upon a surface of the semi-conductor substrate.

Silicon oxides, particularly silicon dioxide (SiO₂) have long been considered to be a passive, insulating component in the construction of electronic devices (i.e, a low-k material). However, in the embodiments presented herein, it is shown that silicon oxides (e.g., SiO₂ and SiOₓ) may serve as the active switching material and electron transport element in electronic devices upon being converted into a switchably conductive state. Without being bound by any theory or mechanism, it is believed that application of one or more voltage pulses or sweeps of appropriate magnitude to a silicon oxide-containing electronic device results in formation of a switchably conductive pathway through the generally non-conductive silicon oxide matrix. The one or more high voltage pulses or sweeps are generally at or above a voltage of the soft electrical soft breakdown potential of the silicon oxide but below a voltage where hard breakdown occurs. Application of the voltage pulses or sweeps of appropriate magnitude results in formation of a switchably conductive pathway containing silicon nanocrystals, silicon nanowires, or metal filaments within the silicon oxide matrix that supports electron transport between electrode terminals. The switchably conductive pathway can be broken by applying a voltage pulse of sufficient magnitude and then reformed by applying a voltage pulse of lower magnitude. Breaking and reforming the conductive pathway corresponds to OFF and ON states of operations, respectively, in a memory device, allowing the electronic devices to operate in distinct OFF and ON states as memory elements and memristors.

In various embodiments, electronic devices prepared by the process disclosed herein include a first electrical contact and a second electrical contact arranged to define a gap region between the two. A switching layer containing a switchably conductive silicon oxide resides in the gap region. At least the first electrical contact is deposited on the substrate. The electronic device exhibits hysteretic current versus voltage properties.

In some embodiments, the switchably conductive silicon oxide is defect-laden SiO₂. Such defect-laden SiO₂ may be produced from SiO₂ residing in the gap region. In preferred embodiments of the present development, defect-laden SiO₂ takes place by removal of porogen from the SiO₂ matrix as will be discussed in greater detail hereinafter.

As used herein, the term “switchably conductive silicon oxide,” refers to, for example, a silicon oxide that exhibits hysteretic current versus voltage behavior after being activated at or above a soft electrical breakdown voltage but below a hard electrical breakdown voltage (i.e., a voltage that results in short circuiting). Due to the hysteretic current versus voltage behavior, electronic devices containing switchably conductive silicon oxide have at least one ON state that is substantially conductive and at least one OFF state that is substantially non-conductive. Without being bound by any theory or mechanism, it is believed that silicon-silicon bonds replace silicon-oxygen bonds in the form of silicon nanocrystals to form a switchably conductive pathway in the parent silicon oxide material.

In some embodiments, the switchably conductive silicon oxide is a non-stoichiometric silicon oxide SiOₓ. In some embodiments, SiOₓ has a stoichiometry between that of silicon monoxide and silicon dioxide (e.g., x is greater than 1 and less than 2). In more specific embodiments, x ranges between 1.5 and 2. In even more specific embodiments, x ranges between 1.6 and 1.8 or between 1.9 and 2. In other embodiments, SiOₓ has a stoichiometry less than that of silicon monoxide (e.g., x is greater than 0 and less than 1).

The RRAM application differs from low-k applications in that the dielectric is deposited in a manner where defects, or pores, are created that can be chemically altered through applied electric fields to induce switchable conductivity through the dielectric. Features such as Si—Si bonding in the film can achieve such properties. In porous low-k applications Si—Si bonding can cause degradation of the insulating properties of the film.

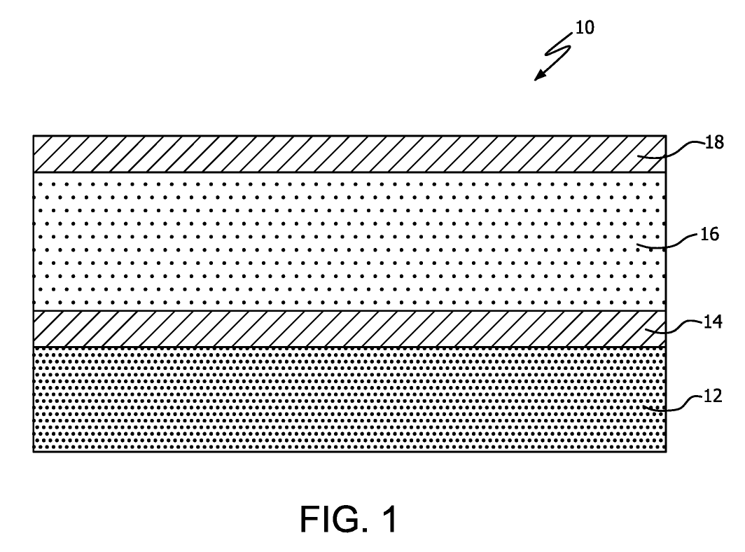

RRAM electronic devices can be constructed in a variety of orientations. In some embodiments, the electronic devices are in a horizontal orientation with the first electrical contact and the second electrical contact spaced apart on a substrate, where the switching layer resides on the substrate between the first electrical contact and the second electrical contact. The process of the present development will now be exemplified with reference to FIG. 1, which shows a schematic illustration of an illustrative horizontally oriented electronic device 10.

The first step of the process of the present development is depositing a first electrode 14 on a substrate 12. Preferably, the substrate 12 is a semiconductor substrate. The semi-conductor substrate can be a material selected from the following: silicon, germanium, silicon oxide, silicon nitride, silicon carbide, silicon carbonitride, carbon doped silicon oxide, boron doped silicon, phosphorous doped silicon, boron doped silicon oxide, phosphorous doped silicon oxide, boron doped silicon nitride, phosphorous doped silicon, silicon nitride, metal such as copper, tungsten, aluminum, cobalt, nickel, tantalum), metal nitride such as titanium nitride, tantalum nitride, metal oxide, III/V such as GaAs, InP GaP and GaN, and a combination thereof.

The electrode may be made from any suitable conducting material such as, for example, Au, Pt, Cu, Al, ITO, graphene, and highly doped Si or any other suitable metal or alloy.

The conducting material of the first electrode 14 may be deposited using one of the following deposition processes: physical vapor deposition, chemical vapor deposition, MOCVD, and atomic layer deposition. In one particular embodiment, the first electrode 14 is deposited using an ALD process. In this embodiment the conducting material may be depositing using an organometallic precursor selected from the following compounds: alkyl metal, metal amides, and metal halides.

The thickness of the electrode layers can vary depending on need or deposition process. For example, if deposited by ALD, the thickness of the electrode layers would typically be 10-20 nm.

For an ALD or MOCVD deposition, process, precursors suitable for use for depositing the electrode material include, for example, (2,4-dimethylpentadienyl)(ethylcyclopentadienyl) ruthenium, bis(2,4-dimethylpentadienyl) ruthenium, 2,4-dimethylpentadienyl) (methylcyclopentadienyl) ruthenium, bis (ethylcyclopentadienyl) ruthenium; metal carbonyl such as dicobalt hexacarbonyl t-butylacetylene (CCTBA) or cyclopentadienyl cobalt dicarbonyl (CpCo(CO)2), Ru3(CO)12; metal amides such as tetrakis(dimethylamino)zirconium (TDMAZ), tetrakis(dimethylamino)titanium (TDMAT), tetrakis(diethylamino)titanium (TDEAT), tetrakis(ethylmethylamino)titanium (TEMAT), tert-butylimino tri(diethylamino)tantalum (TBTDET), tert-butylimino tri(dimethylamino)tantalum (TBTDMT), tert-butylimino tri(ethylmethylamino)tantalum (TBTEMT), ethylimino tri(diethylamino)tantalum (EITDET), ethylimino tri(dimethylamino)tantalum (EITDMT), ethylimino tri(ethylmethylamino)tantalum (EITEMT), tert-amylimino tri(dimethylamino)tantalum (TAIMAT), tert-amylimino tri(diethylamino)tantalum, pentakis(dimethylamino)tantalum, tert-amylimino tri(ethylmethylamino)tantalum, bis(tert-butylimino)bis(dimethylamino)tungsten (BTBMW), bis(tert-butylimino)bis(diethylamino)tungsten, bis(tert-butylimino)bis(ethylmethylamino)tungsten; metal halides such as hafnium tetrachloride, tantalum pentachloride, tungsten hexachloride.

Next, the process of the present development comprises the step of forming a porous resistive memory material layer on the first electrode, wherein the porous resistive memory layer is formed by (i) depositing a gaseous composition comprising a silicon precursor and a porogen precursor and, once deposited, (ii) removing the porogen precursor by exposing the composition to UV radiation.

Still referring to FIG. 1, the process of the present development provides a porous silicon-containing material or film which is employed as a resistive memory material layer 16. Preferably, the deposited porous resistive memory material layer 16 is selected from the group consisting of silicon oxide, carbon doped silicon oxide, silicon oxynitride, silicon nitride, carbon doped silicon nitride, porous silicon oxide, porous silicon carbon doped oxide which can be deposited using conventional chemical vapor deposition methods such as low pressure chemical vapor deposition (LPCVD), chemical vapor deposition (CVD), or plasma enhanced chemical vapor deposition (PECVD) with a silicon precursor such as tetraethoxysilane or any other silicon precursors.

Preferably, the porous silicon-containing film(s) can be deposited using a plasma enhanced chemical vapor deposition (PECVD) or an atomic layer deposition (ALD) process. PECVD is preferred. The porous silicon-containing films can be one layer or multiple layers. In some embodiments, the porous silicon-containing film is deposited using a PECVD process from a composition comprising a silicon precursor and a porogen precursor wherein the amount of carbon is controlled through the selection of silicon precursor and porogen to obtain a film with optimal terminal methyl; optimal bridged carbon; optimal amorphous carbon for porous films. Carbon content and type optimized to provide resultant film post curing that would have defect density providing the optimized electroforming conditions (e.g., lowest applied voltage between the electrodes).

PECVD deposition of the porous silicon-containing film can be adjusted to control the pore density of the deposited film. Pore size is inherently small or microporous with PECVD compared to other depsotion techniques. Optimizing deposition to control pore density and thus pore interconnectivity length enhances the resulting resistive memory materials' switching performance, reduces electroforming potential, and reduces set and reset potentials on the apparatus. In this or alternative embodiments, the pore density of the porous silicon-containing film can be controlled by deposition parameters including silicon precursor /porogen mixing ratio.

The porous silicon-containing material or film (i.e., resistive memory material layer 16) is deposited using a composition comprising a gaseous mixture of a silicon precursor and a porogen precursor. Exemplary silicon precursors include, but are not limited to, tetraethoxysilane, diethoxymethylsilane, dimethoxymethylsilane, di-tertiarybutoxymethylsilane, di-tertiarypentoxymethylsilane, di-tertiarybutoxysilane, di-tertiarypentoxysilane, methyltriacetatoxysilane, dimethylacetatoxysilane, dimethyldiacetoxysilane, dimethyldimethoxysilane, dimethyldiethoxysilane, methyltriethoxysilane, neohexyltriethoxysilane, neopentyltrimethoxysilane, diacetoxymethylsilane, phenyldimethoxysilane, phenyldiethoxysilane, phenyltriethoxysilane, phenyltrimethoxysilane, phenylmethyldimethoxysilane, 1,3,5,7-tetramethyltetracyclosiloxane, octamethyltetracyclosiloxane, 1,1,3,3-tetramethyldisiloxane, 1-neohexyl-1,3,5,7-tetramethylcyclotetrasiloxane, hexamethyldisiloxane, 1,3-dimethyl-1-acetoxy-3-ethoxydislioxane, 1,2-diemthyl-1,2-diacetoxy-1,2-diethoxydisilane, 1,3-dimethyl-1,3-diethoxydisiloxane, 1,3-dimethyl-1,3-diacetoxydisilxane, 1,2-dimethyl,1,1,2,2-tetraacetoxydisilane, 1,2-dimethyl-1,1,2,2-tetraethoxydisilane, 1,3-dimethyl-1-acetoxy-3-ethoxydisiloxane, 1,2-dimethyl-1-acetoxy-2-ethoxydisilane, methylacetoxy(tertiary)butoxysilane, methylsilane, dimethylsilane, trimethylsilane, tetramethylsilane, hexamethyldisilane, tetramethyldisilane, dimethyldisilane, hexamethyldisiloxane (HMDSO), octamethylcyclotetrasiloxane (OMCTS), tetramethylcyclotetrasiloxane (TMCTS), bis(triethoxysilyl)methane, bis(triethoxysilyl)ethane, bis(trimethoxysilyl)methane, bis(trimethoxysilyl)ethane, bis(diethoxymethylsilyl)methane, bis(diethoxymethylsilyl)ethane, bis(methyldiethoxysilyl)methane, (diethoxymethylsilyl)(diethoxysilyl)methane, and mixtures thereof.

The preferred thickness of porous layer is between about 40 to 60 nm. The range could be thinner or thicker—possibly 20-120 nm depending on desired film properties. Much below 20 vnm would probably be too leaky. Much thicker than 100-120nm would be more challenging to get a soft electrical breakdown.

Other silicon precursors that are suitable for use in the present development include those disclosued in U.S. Pat. No. 6,846,515, U.S. Pat. No. 7,384,471, U.S. Pat. No. 7,943,195, U.S. Pat. No. 8,293,001, U.S. Pat. No. 9,061,317, U.S. Pat. No. 8,951,342, U.S. Pat. No. 7,404,990, U.S. Pat. No. 7,470,454, U.S. Pat. No. 7,098,149, and U.S. Pat. No. 7,468,290, the disclosures of which are incorporated herein by reference.

In preferred embodiments, the silicon precursor is tetraethoxysilane, di-tertiarybutoxysilane, or a mixture thereof.

Preferably, the porogen precursor mixed with the silicon precursor is at least one selected from the group consisting of: alpha-terpinene, limonene, cyclohexane, cyclooctane, gamma-terpinene, camphene, dimethylhexadiene, ethylbenzene, norbornadiene, cyclopentene oxide, 1,2,4-trimethylcyclohexane, 1,5-dimethyl-1,5-cyclooctadiene, camphene, adamantane, 1,3-butadiene, substituted dienes, and decahydronaphthelene. In preferred embodiments, the porogen precursoe is selected from the group consisting of norbornadiene, cyclooctane, and mixtures thereof.

In another embodiment, the porous silicon-containing material can be deposited using a composition comprising two or more silicon precursors and a porogen precursor. In these embodiments, the porogen is at least one selected from the group consisting of: alpha-terpinene, limonene, cyclohexane, cyclooctane, gamma-terpinene, camphene, dimethylhexadiene, ethylbenzene, norbornadiene, cyclopentene oxide, 1,2,4-trimethylcyclohexane, 1,5-dimethyl-1,5-cyclooctadiene, camphene, adamantane, 1,3-butadiene, substituted dienes, and decahydronaphthelene; the silicon precursors are selected from the list of compounds aforementioned.

When employed, the dielectric material and the resistive memory material can be deposited using the same silicon precursor(s) under same process conditions or different process conditions. In other embodiments, the dielectric material and the resistive memory material can be deposited using different silicon precursor(s) under same process conditions or different process conditions

In a further embodiment, the porous silicon-containing film can be doped by adding a dopant during the PECVD deposition of porous silicon-containing film. The dopants can be selected from the group consisting of Group II-VI elements including, but not limited to, Zn, Mg, B, P, As, S, Se, and Te. Such dopants could be co-deposited as alkoxides (trimethyl borate, triethyl borate, trimethyl phosphate, trimethyl phosphite), hydrides (AsH₃, PH₃, H₂Se, H₂Te), dimethyl zinc, dimethyl magnesium, dimethyl telluride, dimethyl selenide, trimethyl phosphine, trimethyl arsine or dopants tethered to the silicon-containing precursors, such as diethoxymethylsilylphosphine.

In another embodiment, metal or metal oxide can be added into the porous silicon-containing films for improving the resistive behavior of the porous silicon-containing films. Although Physical Vapor Deposition (PVD) and Metal-Oxide Chemical Vapor Deposition (MOCVD) can be used to deposited metal, PVD or ALD is preferred since the pore of the oxide is typically less than 10 nm. The concentration of metal added to the porous silicon-containing films film can be controlled to preserve the difference in resistivity between the low conductive state and high conductive state when operating as a RRAM device. Exemplary metal precursors that can be used include, but not limited to, metal alkyl such as diethyl zinc, trimethylaluminum, (2,4-dimethylpentadienyl)(ethylcyclopentadienyl) ruthenium, bis(2,4-dimethylpentadienyl) ruthenium, 2,4-dimethylpentadienyl) (methylcyclopentadienyl) ruthenium, bis (ethylcyclopentadienyl) ruthenium; metal carbonyl such as dicobalt hexacarbonyl t-butylacetylene (CCTBA) or cyclopentadienyl cobalt dicarbonyl (CpCo(CO)2), Ru3(CO)12; metal amides such as tetrakis(dimethylamino)zirconium (TDMAZ), tetrakis(diethylamino)zirconium (TDEAZ), tetrakis(ethylmethylamino)zirconium (TEMAZ), tetrakis(dimethylamino)hafnium (TDMAH), tetrakis(diethylamino)hafnium (TDEAH), and tetrakis(ethylmethylamino)hafnium (TEMAH), tetrakis(dimethylamino)titanium (TDMAT), tetrakis(diethylamino)titanium (TDEAT), tetrakis(ethylmethylamino)titanium (TEMAT), tert-butylimino tri(diethylamino)tantalum (TBTDET), tert-butylimino tri(dimethylamino)tantalum (TBTDMT), tert-butylimino tri(ethylmethylamino)tantalurn (TBTEMT), ethylimino tri(diethylamino)tantalum (EITDET), ethylimino tri(dimethylamino)tantalum (EITDMT), ethylimino tri(ethylmethylamino)tantalum (EITEMT), tert-amylimino tri(dimethylamino)tantalum (TAIMAT), tert-amylimino tri(diethylamino)tantalum, pentakis(dimethylamino)tantalum, tert-amylimino tri(ethylmethylamino)tantalum, bis(tert-butylimino)bis(dimethylamino)tungsten (BTBMW), bis(tert-butylimino)bis(diethylamino)tungsten, bis(tert-butylimino)bis(ethylmethylamino)tungsten; metal halides such as hafnium tetrachloride, tantalum pentachloride, tungsten hexachloride.

Yet, in further embodiment, the porous silicon-containing material or layer 16 can comprise a second silicon-containing layer can be incorporated in, or alternatively adjacent to, the porous silicon-containing films. In this embodiment, the silicon-containing layer can be deposited via cyclic chemical vapor deposition (CCVD) or atomic layer deposition. In one particular embodiment, the second silicon-containing layer comprises a monolayer of film consisting of Si H₃ or SiH₂ groups, i.e., converting Si—OH into Si—O—SiH₃ or Si—O—SiH₂by introducing a second silicon-containing precursor to react with the surface of pores inside the porous silicon-containing material, which can be converted into nano silicon particles via eletroforming method in subsequent process. Examples of the second silicon-containing precursor to deposit the second silicon-containing film include, but are not limited to, (a) chlorosilanes such as monochlorosilane and monochlorodisilane; (b) organoaminosilanes such as di-iso-propylaminosilane, di-sec-butylaminosilane, di-iso-propylaminodisilane, di-sec-butylaminodisilane, bis(tert-butylamino)silane, bis(dimethylamino)silane, bis(diethylamino)silane, bis(ethylmethylamino)silane; (c) trisilyamine and its derivatives; and (d) bis(disilylamino)silane H₂Si((NSiH₃)₂)₂. In certain embodiments, curing deposited dense organosilicate glass can be employed to yield a film of varying carbon levels can be accomplished in several ways.

The following are exemplary methods for forming or optimizing the porous silicon-containing films:
(a) using broadband UV radiation and ozone to create pores and strip out all volatile residues, then resulting in porous silicon-containing films having very low extinction coefficient <0.001;
(b) using broadband UV combined with H₂ plasma to create pores and strip Si—CH3 replacing with hydrogen bonded to Si. Such Si—H bonds would serve as potential defect sites in the electroforming process lowering the required potential for; and/or
(c) using EUV (<176 nm) to create pores and strip out Si—CH₃ replacing with Si—H. Such Si—H bonds would serve as potential defect sites in the electroforming process lowering the required potential for activation.

Photocuring for selective removal of porogens from an organosilicate film is conducted under the following conditions.

The environment can be inert (e.g., nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.), or reducing (e.g., dilute or concentrated hydrocarbons, hydrogen, etc.). The temperature is preferably ambient to 500° C. The power is preferably 0 to 5000 W. The wavelength is preferably IR, visible, UV or deep UV (wavelengths <200 nm). The total curing time is preferably 0.01 min to 12 hours.

The porogen in the deposited film may or may not be in the same form as the porogen introduced to the reaction chamber. As well, the porogen removal process may liberate the porogen or fragments thereof from the film. In essence, the porogen reagent, the porogen in the preliminary film, and the porogen being removed may or may not be the same species, although it is preferable that they all originate from the porogen reagent (or porogen substituent). Regardless of whether or not the porogen is unchanged throughout the inventive process, the term “porogen” as used herein is intended to encompass pore-forming reagents (or pore-forming substituents) and derivatives thereof, in whatever forms they are found throughout the entire process of the invention.

Total porosity of the resistive memory material may be from 5 to 75% depending upon the process conditions and the desired final film properties. Such films preferably have a density of less than 2.0 g/ml, or alternatively, less than 1.5 g/ml or less than 1.25 g/ml. Preferably, the resistive memory material of the present development has a density of at least 10% less than that of an analogous silicon-containing film produced without a porogen, more preferably at least 20% less.

The method of the present development also includes the step of depositing a second electrode 18 on top of the porous resistive memory material layer 16. The same process and conductive materials described above in connection with the first electrode 14 can be employed to deposit the second electrode 18.

Certain embodiments of the deposition methods described herein for forming one or more of the materials contained within the apparatus use one or more purge gases to purge away unconsumed reactants and/or reaction byproducts. Suitable purge gas(es) are gases that do not react with the precursors used to deposit the device. Exemplary purge gases include, but are not limited to, argon (Ar), nitrogen (N₂), helium (He), neon, hydrogen (H₂), and combinations thereof.

Energy is applied to the at least one of the silicon-containing precursor, porogen precursor, oxygen-containing source, nitrogen-containing source, reducing agent, other precursors and/or combination thereof to induce reaction and to form the silicon-containing film or coating on the substrate. Such energy can be provided by, but not limited to, thermal, plasma, microwave plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

The precursors may be delivered to the reaction chamber such as a PECVD or ALD reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, Minn., to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

In certain embodiments, the gas lines connecting from the precursor canisters to the reaction chamber are heated to one or more temperatures depending upon the process requirements and the container of the at least one silicon-containing precursor is kept at one or more temperatures for bubbling. In other embodiments, a solution comprising the at least one silicon-containing precursor is injected into a vaporizer kept at one or more temperatures for direct liquid injection.

The temperature of the reactor or deposition chamber for the deposition may range from one of the following endpoints: ambient temperature or 25° C.; 100° C.; 200° C.; 250° C.; 300° C.; 350° C.; 400° C.; 450° C.; 500° C. and any combinations thereof. In this regard, the temperature of the reactor or deposition chamber for the deposition may range from ambient temperature to 1000° C., from about 150° C. to about 400° C., from about 200° C. to about 400° C., from about 300° C. to 600° C., or any combinations of the temperature end-points described herein.

The pressure of the reactor or deposition chamber may range from about 0.1 Torr to about 760 Torr, preferably less than 10torr. The respective step of supplying the precursors, the oxygen source, the nitrogen source, and/or other precursors, source gases, and/or reagents may be performed by changing the time for supplying them to change the stoichiometric composition of the resulting silicon-containing film.

Examples of configurations of devices that can be made by the process of the present development may be found in U.S. Pat. No. 9,129,676, which is incorporated herein by reference.

The invention will be illustrated in more detail with reference to the following Examples, but it should be understood that the present invention is not deemed to be limited thereto.

### EXAMPLES

The following examples will show device results obtained relative to the process conditions used to deposit films and create pores in the film.

All experiments were performed on an Applied Materials Precision-5000 system in a 200 mm DxZ chamber fitted with an Advance Energy 2000 rf generator, using an undoped TEOS process kit. The recipe involved the following basic steps: initial set-up and stabilization of gas flows, deposition, and purge/evacuation of chamber prior to wafer removal.

Once films were deposited memory test structures were built on the wafers as follows. A top electrode made from gold was deposited on the porous oxide. The low-resistivity Si substrate served as bottom electrode. A total of five memory cell arrays were built with each containing 20 cells across the wafer.

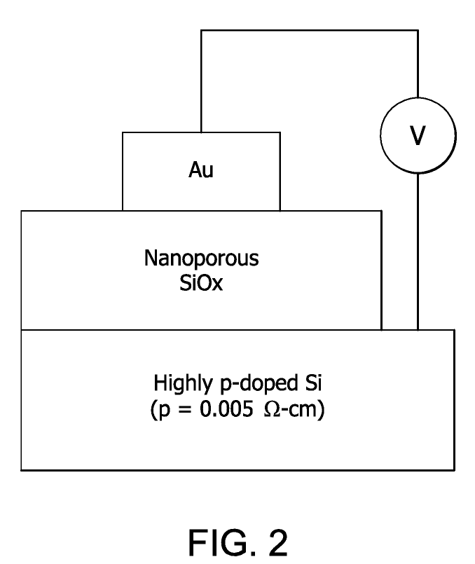

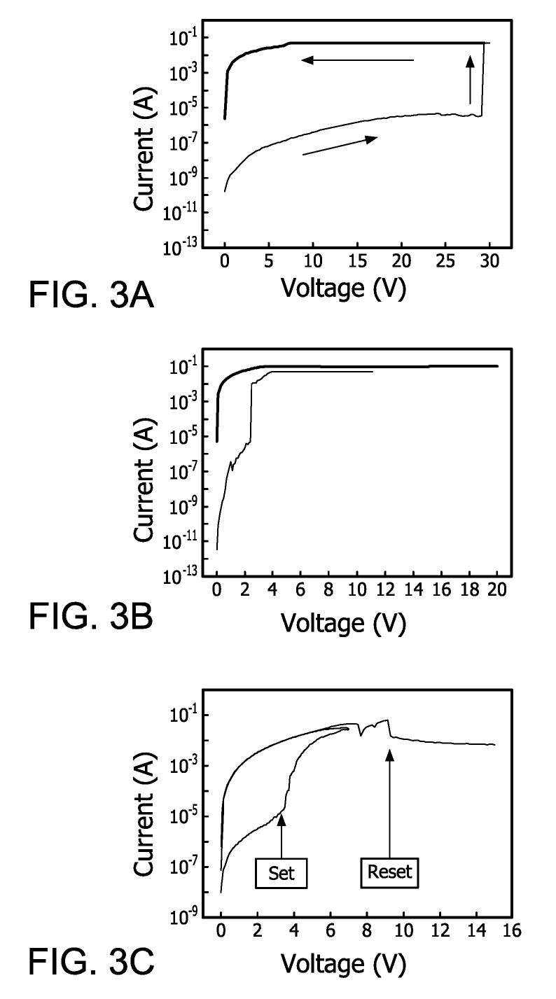

All 100 cells or devices per wafer were tested using current-voltage sweeps across the porous dielectric. The profile of current vs. voltage was used to determine if the devices operated as memory switching units, were non-conductive until a hard breakdown of the dielectric occurs, or were conductive or leaky at low applied voltages. Two of these 3 conditions (hard breakdown, leaky cells) would indicate a failed device. A hysteretic voltage-current sweep with clear set and reset points would indicate a working switchable memory device. FIG. 2 illustrates the test structure for obtaining current-voltage sweeps. FIGS. 3 A-C show the three responses obtained for cells that a) were not sufficiently conductive until a hard electrical breakdown occurred, b) were too conductive or leaky at low applied voltages, or c) showed hysteretic current-voltage sweeps suitable as switching memory devices. Specifically, FIG. 3A illustrates the forward voltage sweep which does not show increase in conductivity until high potentials are applied and a hard electrical breakdown or short circuit develops in the SiOx film. The reverse sweep shows the impact of the short circuit as current density remains high during the sweep back to 0 Volts. FIG. 3B illustrates that the forward sweep shows a significant increase in conductivity at a very low applied voltage indicating that the SiOx film is too leaky or conductive resulting in a hard breakdown at a very low potential. FIG. 3C illustrates a hysteretic current-voltage sweep showing hysteretic current-voltage profiles of a resistive memory device.

Substrate Conditioning: Substrates used for this development work were low resistivity p type Si (0.005 Ω-cm). At room temperature these substrates contained a surface native oxide of ca. 8-10 A, which is a high quality thermal oxide that is defect free. It was postulated that this native oxide could prevent the completion of defect driven conductive pathways to the Si susbtrate. Prior to deposition of SiOx films, the dense thermal SiOx native oxide surface was removed for some wafers. The first method of removal evaluated was a wet etch using dilute (5%) HF solution. Wafers were dipped in dilute HF solution for a period of 10 minutes with aggitation, then were rinsed in DI water and dried. These wafers were subsequently taken to the P5000 for deposition within 5 minutes of native oxide strip, to prevent reoxidation of the surface.

An alternative approach to HF removal of native oxide was to use an in-situ plasma or Remote Plasma Source (RPS) based plasma to generate F radicals that would etch the native oxide. In this process the wafer would be put into the deposition chamber and an in-situ NF₃ or RPS NF₃ plasma ignited and used to strip away the native oxide. As indicated in Table I below, it was determined that the plasma based approach for removing native oxide significantly improved the yield for switching memory devices.

Example 1: Comparison of native oxide removal processes were conducted by depositing SiOx films using process conditions of 850 mg/min cyclooctane flow; 150 mg/min DEMS flow; 100 sccm CO₂ carrier gas; 20 sccm O₂, 700 watts of applied plasma power; chamber pressure of 8 torr; susceptor temperature of 300° C., deposition time 90 sec yielding pre UV cure film thicknesses of 45-55 nm. Three substrate conditioning methods were evaluated: Dilute HF wet etch, in-situ NF₃ plasma, no Native Oxide strip. Testing results for two 20 device arrays are contained in Table I: The in-situ NF₃ plasma used to remove native oxide provided the highest yield out of 20 devices per array.

TABLE 1
Device yield for a single process using three differing
approaches of substrate treatment prior to deposition:
Wet etching of native oxide, in-situ plasma etching of
native oxide, and no removal of native oxide.

| | Percentage Yield out of | Percentage Yield out of |
|---|---|---|
| Native Oxide | 20 cells and Device | 20 cells and Device |
| Removal Method | Array #1 | Array #2 |
| Wet etching - HF | 5% | 15% |
| Strip | | |
| In-Situ NF₃ Plasma | 95% | 100% |
| No Native Oxide | 25% | 0% |
| Strip | | |

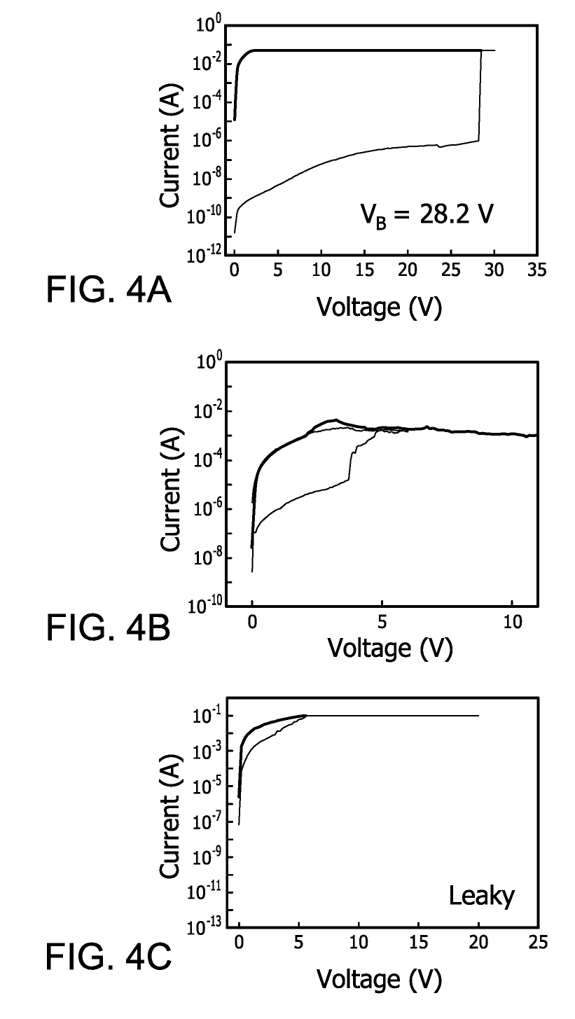

Example 2: Comparison of film porosity on electrical switching properties were conducted by using 3 differing mixing ratios of structure former to porogen. These included 70% porogen/30% structure former; 80% porogen/20% structure former; 90% porogen/10% structure former. It was thought that increasing the conduction of SiOx films requires creating sufficient defect density to allow current to pass thru the film. Two approaches to achieving this were based on pore size or pore density. Use of mesopores in the 5-10 nm diameter can create a continuous porous network that is interconnected from one electrode to the other. Porous films deposited using PECVD typically yield micropores or pores having a diameter of <2 nm. With smaller pore sizes, pore density or porous volume, typically expressed as percent porosity, becomes more critical for establishing conductive pathways. In the application of PECVD for porous SiOx films, pore density can be controlled by among other factors the selection of structure former to porogen ratio. If insufficient pore density is present, a conductive pathway between electrodes will not be established and the film will ultimately experience a hard electrical breakdown. If the porosity is too great, this combine with other factors affecting conductivity including the amount and type of carbon in the film, causes SiOx based porous films to become conductive at low applied potentials and short circuit, or the current can leak between electrodes in the OFF state (leakage current too high). The optimum porosity will provide films with hysteretic current-voltage sweeps that will set at a relatively low voltage, reset at a higher voltage and be capable of switching back and forth as the applied voltage is varied. The following 3 films were deposited under similar conditions: Total precursor flows 1000 mg/min were used. In 70:30 case this consisted of 700 mg/min Cyclooctane and 300 mg/min TEOS; 80:20-800 mg/min Cyclooctane and 200 mg/min TEOS; 90:10-900 mg/min Cyclooctane and 100 mg/min TEOS. Carrier gas flows of 100 sccm CO2 each for TEOS and cyclooctane were used; O₂ flow of 20 sccm; Plasma power was 700 watts; chamber pressure 8 torr, deposition temperature of 300° C. Films with thickness of 45-55 nm were deposited for all three conditions and then subsequently annealed using a broad band UV source for 90 sec to remove porogen and create pores. The films porosity volume were determined by Ellipsometric Porosimitry (EP) and carbon content by X-ray Photoelectron Spectroscopy (XPS) with values contained in Table II below: As expected the process with the highest porogen to structure former ratio (90:10) contained the highest porosity and carbon content. These three films were used to construct memory devices and tested as described above. The current-voltage profiles obtained for each film are shown in FIGS. 4A-C. Specifically, FIG. 4A shows a hard breakdown of the dielectric at 28 V of applied potential. This films had a pore density of ca. 25% and very low residual carbon. FIG. 4B shows the hysteretic current-voltage profile of a resistive memory switching device. This film had a pore density of >25% and carbon content of <10%. FIG. 4C shows a profile of a film that electrically breaks down at very low applied potentials and is not sufficiently insulating to serve as a memory switching device. This film had porosity >30% and residual carbon >20%. The combination of high porosity and residual carbon could have led to the premature electrical breakdown at low applied potentials.

TABLE II
Relationship between mixing ratio of porogen to structure
former during PECVD and pore density and carbon content
in deposited film.

| Porogen to Structure | | |
|---|---|---|
| Former Ratio | Film Pore Density (%) | Carbon Content (%) |
| 70:30 | 24-26% | 5% |
| 80:20 | 31-34% | 9% |
| 90:10 | 35-38% | 23% |

The device results indicated that in films with insufficient porosity, such as shown in FIG. 3A, defect driven soft breakdown does not occur and hard breakdown or the film becoming irreversibly short circuited results as shown in the current-voltage profile. The device results also indicate that films with high porosity and high residual carbon content can become too readily conductive or leaky at low applied potentials. The films with porosity of >25% and carbon content <20% demonstrated memory switching capability. The amount of porosity and carbon content in the film is tunable based on the deposition and curing conditions used to deposit and cure the films.

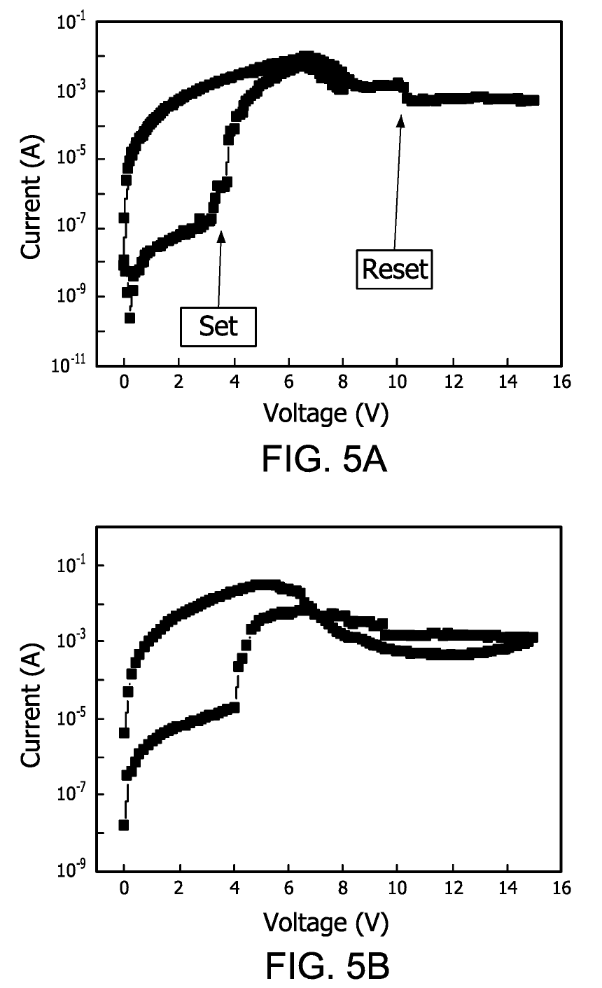

Example 3: After discovery of the required substrate conditioning and sufficient pore density to allow conductive pathways to traverse the entire thickness of the film, films were deposited and tested using porogen to structure former ratios of 80:20 and 85:15. These films were cured for sufficiently long periods of time to reduce carbon content to 20%. The deposition conditions consisted of 1000 mg/min total precursor flows of structure former TEOS (150 or 200 mg/min) and Cyclooctane (850 or 800 mg/min), 100 sccm CO₂ carrier gas for each precursor, O₂ flow of 20 sccm; 700 watts RF power, 8 torr chamber pressure, 300 C deposition temperature. Films with thickness of 45-60 nm were deposited and UV cured using a broad band UV source for 90 sec. The films were subsequently used to construct memory devices as shown in FIG. 2. The films were evaluated for switching capability with representative current-voltage sweep profiles shown in FIGS. 5A and 5B, which demonstrate hysteretic profiles for porous PECVD based SiOx films deposited using porogen to structure former ratios of 80:20 (5A) and 85:15 (5B). Both films showed soft breakdown of ca. 3.5-4.5 V and deactivation of ca. 10 V.

Both films showed hysteretic switching properties indicating the potential for use as a resistive memory switching medium. The specific film properties of porosity and carbon content are shown in Table III below.

TABLE III
Porosity and carbon content of PECVD based SiOx films
deposited from porogen to structure former ratio of
80:20 and 85:15.

| Porogen to Structure | | |
|---|---|---|
| Former Ratio | Film Pore Density (%) | Carbon Content (%) |
| 80:20 | 31% | 12% |
| 85:15 | 34% | 20% |

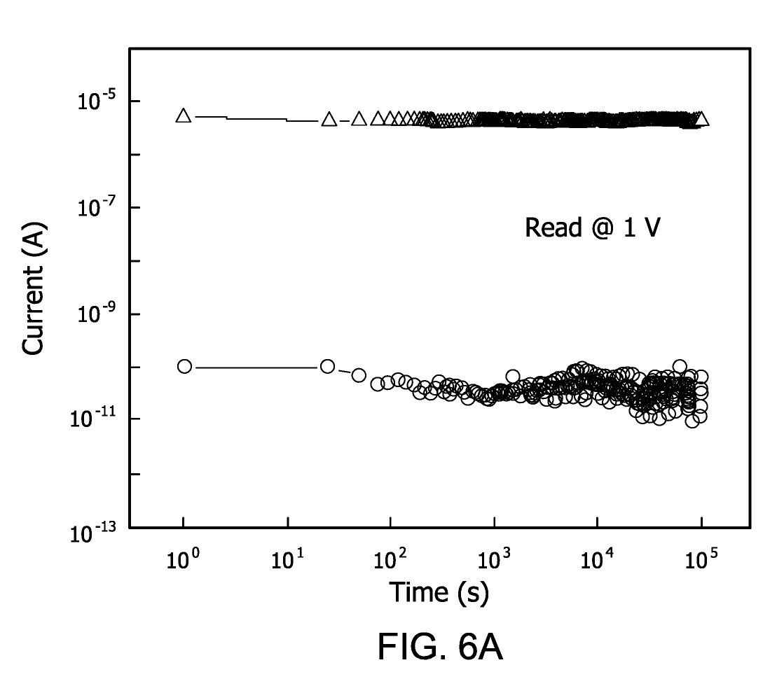

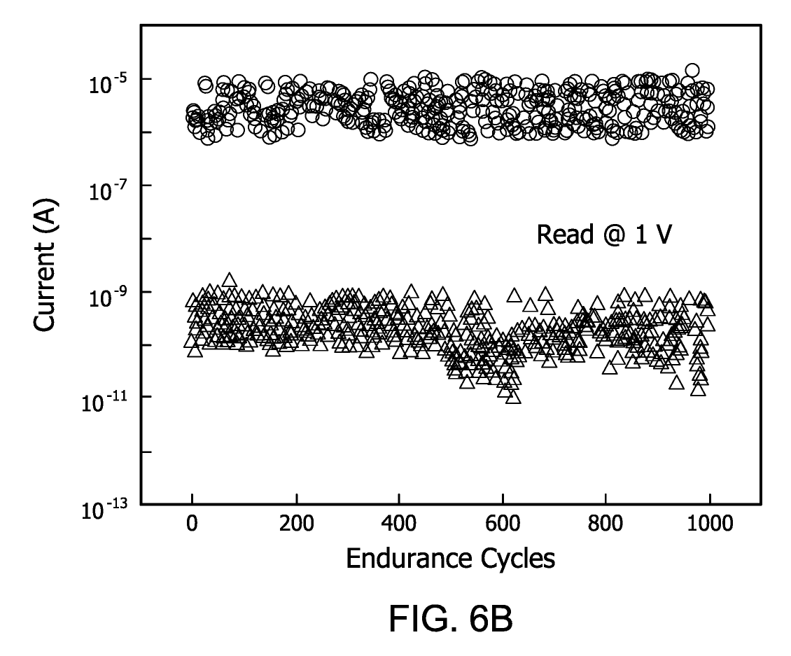

Example 4: A critical component to successful deployment of porous PECVD SiOx based films is the ability to retain the programmed conductivity, or ON-OFF state for extended periods of time. This memory retention was tested on a device fabricated from the films deposited in FIG. 5B and is shown in FIG. 6A. Measuring current at an applied potential of 1 V a difference in current density of >10⁴ Acre was maintained for a period of 10⁵ sec.

Another critical component to successful deployment of porous PECVD SiOx based films is the ability to switch from conductive to non-conductive states for large numbers of switching cycles. The programming capability of PECVD based porous SiOx films was tested by repeated switching from conductive or ON state to insulating or OFF state, with the current measured at 1V. The measured currents for each state are shown in FIG. 6B where the device was found to provide a difference of >10³ in current density between conductive states for 10³ switching cycles.

The embodiments illustrated and discussed in this specification are intended only to teach those skilled in the art the best way known to the inventors to make and use the invention. Nothing in this specification should be considered as limiting the scope of the present invention. All examples presented are representative and non-limiting. The above-described embodiments of the invention may be modified or varied, without departing from the invention, as appreciated by those skilled in the art in light of the above teachings. While the invention is described with respect to a wide mouth container, the function of the panel curvatures according to the invention should work with a standard finish (i.e., not a wide mouth neck with a finish). It is therefore to be understood that, within the scope of the claims and their equivalents, the invention may be practiced otherwise than as specifically described.

We claim:

1. A process for forming a resistive random-access memory device, the process comprising the steps of:
depositing a first electrode on a substrate;
forming a porous resistive memory material layer on the first electrode, wherein the porous resistive memory layer is formed by (i) depositing a gaseous composition comprising a silicon precursor and a porogen precursor and, once deposited, (ii) removing the porogen precursor by exposing the composition to UV radiation; and
depositing a second electrode on top of the porous resistive memory material layer.

2. The process of claim 1 wherein the silicon precursor is at least one selected from the group consisting of: tetraethoxysilane, diethoxymethylsilane, dimethoxymethylsilane, di-(tertiary)butoxymethylsilane, di-tertiarypentoxymethylsilane, di-tertiarybutoxysilane, di-tertiarypentoxysilane, methyltriacetatoxysilane, dimethylacetatoxysilane, dimethyldiacetoxysilane, dimethyldimethoxysilane, dimethyldiethoxysilane, methyltriethoxysilane, neohexyltriethoxysilane, neopentyltrimethoxysilane, diacetoxymethylsilane, phenyldimethoxysilane, phenyldiethoxysilane, phenyltriethoxysilane, phenyltrimethoxysilane, phenylmethyldimethoxysilane, 1,3,5,7-tetramethyltetracyclosiloxane, octamethyltetracyclosiloxane, 1,1,3,3-tetramethyldisiloxane, 1-neohexyl-1,3,5,7-tetramethylcyclotetrasiloxane, hexamethyldisiloxane, 1,3-dimethyl-1-acetoxy-3-ethoxydislioxane, 1,2-diemthyl-1,2-diacetoxy-1,2-diethoxydisilane, 1,3-dimethyl-1,3-diethoxydisiloxane, 1,3-dimethyl-1,3-diacetoxydisilxane, 1,2-dimethyl,1,1,2,2-tetraacetoxydisilane, 1,2-dimethyl-1,1,2,2-tetraethoxydisilane, 1,3-dimethyl-1-acetoxy-3-ethoxydisiloxane, 1,2-dimethyl-1-acetoxy-2-ethoxydisilane, methylacetoxy(tertiary)butoxysilane, methylsilane, dimethylsilane, trimethylsilane, tetramethylsilane, hexamethyldisilane, tetramethyldisilane, dimethyldisilane, hexamethyldisiloxane (HMDSO), octamethylcyclotetrasiloxane (OMCTS), tetramethylcyclotetrasiloxane (TMCTS), bis(triethoxysilyl)methane, bis(triethoxysilyl)ethane, bis(trimethoxysilyl)methane, bis(trimethoxysilyl)ethane, bis(diethoxymethylsilyl)methane, bis(diethoxymethylsilyl)ethane, bis(methyldiethoxysilyl)methane, (diethoxymethylsilyl)(diethoxysilyl)methane, and mixtures thereof.

3. The process of claim 2 wherein the silicon precursor is selected from the group consisting of di-tertiarybutoxysilane, di-tertiarypentoxysilane, tetraethoxysilane (TEOS), tetramethoxysilane and a mixture thereof.

4. The process of claim 1 wherein the porogen is at least one selected from the group consisting of: alpha-terpinene, limonene, cyclohexane, cyclooctane, gamma-terpinene, camphene, dimethylhexadiene, ethylbenzene, norbornadiene, cyclopentene oxide, 1,2,4-trimethylcyclohexane, 1,5-dimethyl-1,5-cyclooctadiene, camphene, adamantane, 1,3-butadiene, substituted dienes, and decahydronaphthelene.

5. The process of claim 3 wherein the porogen comprises norbornadiene, alpha-terpinene or cyclooctane.

6. The process of claim 1 wherein the gaseous composition comprising a silicon precursor and a porogen precursor is deposited by either a plasma enhanced chemical vapor deposition (PECVD) or a plasma enhanced cyclic chemical vapor deposition (PECCVD) process.

7. The process of claim 1 wherein the substrate is a material selected from the group consisting of: silicon, germanium, silicon oxide, silicon nitride, silicon carbide, silicon carbonitride, carbon doped silicon oxide, boron doped silicon, phosphorous doped silicon, boron doped silicon oxide, phosphorous doped silicon oxide, boron doped silicon nitride, phosphorous doped silicon, silicon nitride, copper, tungsten, aluminum, cobalt, nickel, tantalum, titanium nitride, tantalum nitride, metal oxide, GaAs, InP GaP and GaN, and a combination thereof.

8. The process of claim 1 wherein the first electrode is a metal deposited from a precursor selected from the group consisting of an alkyl metal, a metal amides, a metal alkoxide, and a metal halide.

9. The process of claim 1 further comprising adding a dopant when depositing the gaseous composition comprising the silicon precursor and the porogen precursor.

10. The process of claim 9 wherein the dopant is selected from the group consisting of Zn, Mg, B, P, As, S, Se, and Te.

11. The process of claim 1 further comprising adding a metal or metal oxide precursor when depositing the gaseous composition comprising the silicon precursor and the porogen precursor.

12. The process of claim 11 wherein the metal or metal oxide is selected from the group consisting of diethyl zinc, trimethylaluminum, (2,4-dimethylpentadienyl)(ethylcyclopentadienyl) ruthenium, bis(2,4-dimethylpentadienyl) ruthenium, 2,4-dimethylpentadienyl) (methylcyclopentadienyl) ruthenium, bis (ethylcyclopentadienyl) ruthenium, dicobalt hexacarbonyl t-butylacetylene (CCTBA) or cyclopentadienyl cobalt dicarbonyl (CpCo(CO)₂), Ru₃(CO)₁₂; metal amides such as tetrakis(dimethylamino)zirconium (TDMAZ), tetrakis(diethylamino)zirconium (TDEAZ), tetrakis(ethylmethylamino)zirconium (TEMAZ), tetrakis(dimethylamino)hafnium (TDMAH), tetrakis(diethylamino)hafnium (TDEAH), and tetrakis(ethylmethylamino)hafnium (TEMAH), tetrakis(dimethylamino)titanium (TDMAT), tetrakis(diethylamino)titanium (TDEAT), tetrakis(ethylmethylamino)titanium (TEMAT), tert-butylimino tri(diethylamino)tantalum (TBTDET), tert-butylimino tri(dimethylamino)tantalum (TBTDMT), tert-butylimino tri(ethylmethylamino)tantalum (TBTEMT), ethylimino tri(diethylamino)tantalum (EITDET), ethylimino tri(dimethylamino)tantalum (EITDMT), ethylimino tri(ethylmethylamino)tantalum (EITEMT), tert-amylimino tri(dimethylamino)tantalum (TAIMAT), tert-amylimino tri(diethylamino)tantalum, pentakis(dimethylamino)tantalum, tert-amylimino tri(ethylmethylamino)tantalum, bis(tert-butylimino)bis(dimethylamino)tungsten (BTBMW), bis(tert-butylimino)bis(diethylamino)tungsten, bis(tert-butylimino)bis(ethylmethylamino)tungsten, hafnium tetrachloride, tantalum pentachloride, and tungsten hexachloride.

13. The process of claim 1 further comprising the step of depositing a second porous silicon-containing layer.

14. The process of claim 13 wherein the second porous silicon-containing layer is formed by depositing at least one second silicon-containing precursor selected from the group consisting of monochlorosilane, monochlorodisilane, di-iso-propylaminosilane, di-sec-butylaminosilane, di-iso-propylaminodisilane, di-sec-butylaminodisilane, bis(tert-butylamino)silane, bis(dimethylamino)silane, bis(diethylamino)silane, bis(ethylmethylamino)silane, trisilyamine and its derivatives, bis(disilylamino)silane, and H₂Si((NSiH₃)₂)₂.

15. The process of claim 1 wherein the porous resistive memory material layer is selected from the group consisting of SiOₓ, SiOₓH, Si, OₓN_{y}, SiOₓN_{y}H, SiOₓC_{z}, SiOₓC_{z}H, and combinations thereof, wherein each of x, y, and z are equal or greater than 1 or equal or less than 2.
